(19) United States
(12) Patent Application Publication
(10) Pub. No.: US 2012/0153396 A1
(43) Pub. Date: Jun. 21, 2012

(54) SEMICONDUCTOR DEVICE

(75) Inventors: Masayuki Sugiura, Kanagawa-ken (JP); Toshiki Seshita, Kanagawa-ken (JP); Yoshimoto Sagae, Kanagawa-ken (JP)

(73) Assignee: KABUSHIKI KAISHA TOSHIBA, Tokyo (JP)

(21) Appl. No.: 13/227,641

(22) Filed: Sep. 8, 2011

(30) Foreign Application Priority Data
Dec. 21, 2010 (JP) 2010-284903

(51) Int. Cl. H01L 27/06

(52) U.S. Cl. 257/350; 257/E27.016

(57) ABSTRACT

According to an embodiment, a semiconductor device including a switch circuit includes a first gate electrode provided between a source region and a drain region of an FET and a second gate electrode provided between the first gate electrode and the drain region. The semiconductor device also includes a control terminal electrically connected to an intermediate region between the first gate electrode and the second gate electrode, the control terminal being placed at a ground potential corresponding to ON state of the FET, and the control terminal being placed at a positive potential or a negative potential corresponding to OFF state of the FET.

### CROSS-REFERENCE TO RELATED APPLICATIONS

This application is based upon and claims the benefit of priority from Japanese Patent Application No. 2010-284903, filed on Dec. 21, 2010; the entire contents of which are incorporated herein by reference.

### FIELD

Embodiments are generally related to a semiconductor device.

### BACKGROUND

A semiconductor device provided in a semiconductor layer formed on an insulating layer, such as SOI (silicon on insulator), is characterized by low leakage current because of its small capacitive component attributed to the substrate. Thus, such a semiconductor device is widely used as a high speed digital device with low power consumption. Furthermore, because of its superior performance in high speed operation, such a semiconductor device is also used as a radio frequency device.

For instance, a radio frequency switch integrated circuit (IC) based on the SOI structure enables further cost reduction as compared with the existing radio frequency switch IC based on compound semiconductors. Furthermore, in the SOI structure, a control including CMOS (complementary metal oxide semiconductor) circuits and the radio frequency switch IC can be integrated on the same chip. Thus, a compact switch module can also be realized.

However, to ensure the off-breakdown voltage for the amplitude of radio frequency signals, the radio frequency switch IC on the SOI structure uses a circuit in which FETs (field effect transistors) are connected in series and in multiple stages (stack structure). The size of the radio frequency switch IC is determined by the area required for the basic structure of FET, i.e., source, gate, and drain. Hence, increasing the number of stages in the stack structure for higher breakdown voltage interferes with downsizing. Thus, there is need for a semiconductor device that can be downsized while maintaining the breakdown voltage for high power radio frequency signals.

### BRIEF DESCRIPTION OF THE DRAWINGS

FIG. 1 is a circuit diagram illustrating a part of a switch circuit of a semiconductor device according to an embodiment;

FIG. 2 is a plan view schematically illustrating a FET included in the switch circuit according to the embodiment;

FIG. 3 is a cross-sectional view schematically illustrating the FET;

FIG. 4 is a cross-sectional view schematically illustrating an operation of the FET according to the embodiment;

FIG. 5 is a cross-sectional view schematically illustrating another operation of the FET according to the embodiment;

FIG. 6 is a circuit diagram illustrating a semiconductor device including a switch circuit and a control section.

### DETAILED DESCRIPTION

In general, according to an embodiment, a semiconductor device including a switch circuit includes a first gate electrode provided between a source region and a drain region of an FET and a second gate electrode provided between the first gate electrode and the drain region. The semiconductor device also includes a control terminal electrically connected to an intermediate region between the first gate electrode and the second gate electrode, a ground potential being supplied to the control terminal corresponding to ON state of the FET, and a positive potential or a negative potential being provided to the control terminal corresponding to OFF state of the FET.

Embodiments of the invention will now be described with reference to the drawings. In the following embodiments, like portions in the drawings are labeled with like reference numerals, and the detailed description thereof is omitted as appropriate. The different portions are described as appropriate.

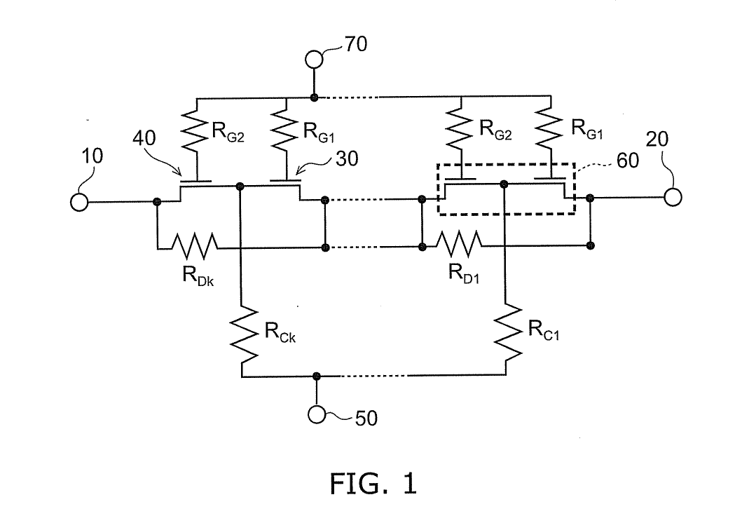

FIG. 1 is a circuit diagram showing part of a switch circuit of a semiconductor device according to an embodiment. For instance, the switch circuit shown in this figure includes a plurality of FETs 60 provided in a semiconductor layer formed on an insulating film. The switch circuit turns on or off the signal pathway of radio frequency signals between an input terminal 10 and an output terminal 20.

The FET 60 according to the embodiment is a dual gate FET including two gate electrodes 30 and 40. The FET 60 further includes a control terminal 50 for controlling the potential of the intermediate region between the gate electrode 30 and the gate electrode 40.

The FET 60 is turned on or off by the gate voltage supplied to the first gate electrode 30 and the second gate electrode 40. For instance, the FET 60 can be controlled as follows. When the FET 60 is in the ON state, the ground potential is supplied to the control terminal 50. When the FET 60 is in the OFF state, a positive potential or a negative potential is supplied to the control terminal 50.

Thus, by using an additional terminal to control the potential of the intergate region of the dual gate FET, the potential between the gates can be stabilized when the FET is in the OFF state. This can prevent the voltage between the two gates from being unbalanced, and suppress the decreased of the breakdown voltage of FET.

Furthermore, by fixing the potential between the gate electrodes 30 and 40 at either a positive potential or a negative potential, the width of the depletion layer at the gate edge can be controlled. Thus, it becomes possible to suppress radio frequency distortion induced by the variation of the depletion layer width at the gate edge under application of radio frequency signals.

The control voltage applied to the control terminal 50 can use, for instance, a gate voltage supplied or controlled inside the circuit to turn on the FET 60. This can simplify the circuit configuration. It is also possible to supply an appropriate voltage depending on the characteristics of the FET 60.

In the switch circuit shown in FIG. 1, plurality of FETs 60 are connected in series. In the OFF state between the input terminal 10 and the output terminal 20, the voltage applied between these terminals is held by the plurality of FETs 60.

For instance, radio frequency signals at several watts are switched in a switch circuit used for the front end of a mobile terminal. Here, the maximum voltage amplitude of the radio frequency signal is several ten volts. Thus, a high voltage which cannot be held by a microfabricated FET 60 integrated with high density is applied to a terminal in the OFF state. Hence, as described in the embodiment, a plurality of FETs connected in series are provided between the input and output terminals.

To increase the breakdown voltage between the input terminal 10 and the output terminal 20, the voltage applied to each FET 60 is preferably designed to be equal. Thus, a plurality of series connected resistors R_{D1}-R_{Dk} can be provided in parallel with the FETs 60, as shown in FIG. 1, in order to equally divide the voltage applied between the input terminal 10 and the output terminal 20.

For instance, each of the resistors R_{D1}-R_{Dk} can be provided with a resistance of approximately 20-50 kΩ. While maintaining a high resistance of 100 kΩ or more between the input terminal 10 and the output terminal 20, an equal voltage divided by the resistors R_{D1}-R_{Dk} can be applied between the source and the drain of each FET 60.

As mentioned above, the voltage between the input terminal 10 and the output terminal 20 can be equally divided by equalizing the values of the resistors R_{D1}-R_{Dk}. On the other hand, there may be cases where the plurality of FETs 60 are to be supplied with different voltages. In such cases, the values of the resistors R_{D1}-R_{Dk} can be determined depending on the voltages applied to the respective FETs 60.

In order to suppress leakage of radio frequency signals to the gate terminal 70 through the gate capacitance of each FET 60, gate resistors R_{G1} and R_{G2} are provided between the gate terminal 70 and the gate electrodes 30 and 40, respectively. The gate resistors R_{G1} and R_{G2} are provided with a value sufficiently higher than the gate impedance. For instance, the gate resistors R_{G1} and R_{G2} are provided with a resistance of approximately 150 kΩ.

On the other hand, control resistors R_{C1}-R_{Ck} are provided also between the control terminal 50 and the intermediate region between the gate electrodes 30 and 40 to suppress leakage of radio frequency signals to the control terminal 50. Each of the control resistors R_{C1}-R_{Ck} is also provided with a resistance of e.g. approximately 150 kΩ. This resistance is sufficiently higher than the impedance in the ON state between the input terminal 10 and the output terminal 20, such as 50Ω. By using such a circuit, a low loss switch circuit can be configured to be functional for high power radio frequency signals.

Furthermore, as shown in FIG. 1, the control terminal 50 can be connected, independently of the source and the drain, to the intermediate region between the gate electrode 30 and the gate electrode 40. Thus, the potential of the intermediate region can be controlled without affecting the potential of the input terminal 10 and the output terminal 20.

The FET 60 of the dual gate structure shown in FIG. 1 has a configuration with two FETs connected in series, where the intermediate region between the gate electrode 30 and the gate electrode 40 is regarded as a source or drain. That is, it can be regarded that the source and the drain in two FETs are replaced by one intermediate region. Thus, the source-drain breakdown voltage can be ensured to be a value of two FETs connected in series, and the area corresponding to either the source or the drain can be eliminated.

Furthermore, also in a multi-gate FET in which two or more gate electrodes are provided between the source and the drain, the breakdown voltage can be ensured corresponding to a plurality of FETs connected in series, and the area of the circuit can be eliminated likewise. However, conventionally, such area reduction by multi-gate FETs is limited to the reduction of the area of the source region or the drain region. Thus, there has been a limit to the downsizing of semiconductor devices.

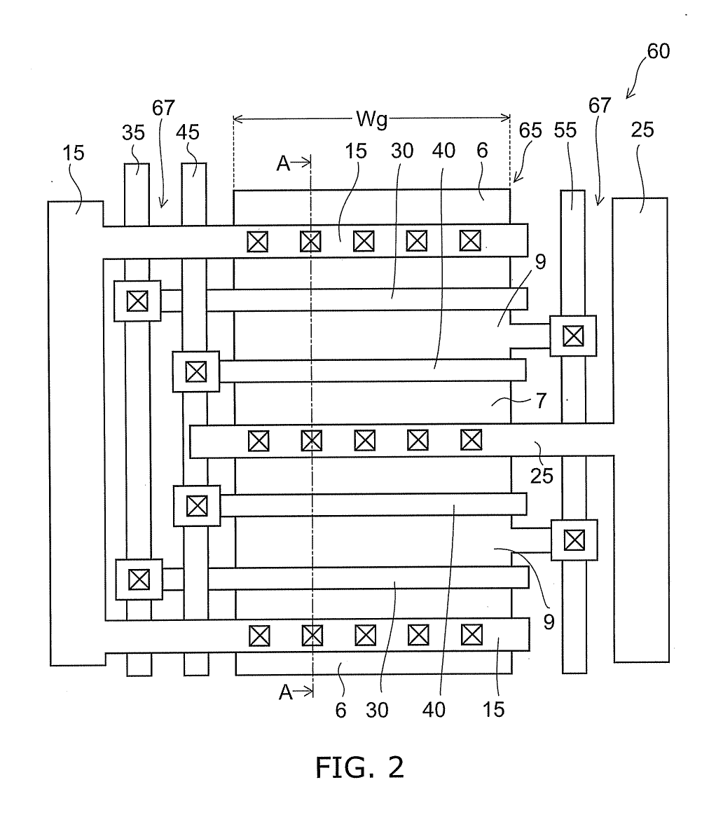

In contrast, the FET 60 according to this embodiment may realize downsizing of semiconductor devices beyond the above limit. In the following, the area reduction possible for the FET 60 is described with reference to FIGS. 2 to 5.

FIG. 2 is a plan view schematically showing the FET 60. The FET 60 is provided in a device region 65 surrounded with an isolation region 67. The device region 65 includes source regions 6, a drain region 7, and intermediate regions 9. The source regions 6 and the intermediate regions 9 are symmetrically located on both sides of the drain region 7 in the vertical direction of the figure.

As shown in this figure, two source regions 6 and two intermediate regions 9 are located symmetrically with respect to the drain region 7. Thus, the effective gate width W_{g} is doubled to reduce the on-resistance.

Two gate electrodes 30 and 40 are located between the source region 6 and the drain region 7. The first gate electrode 30 is provided between the source region 6 and the second gate electrode 40, and the second gate electrode 30 are provided between to the first gate electrode 30 and the drain region 7. The intermediate region 9 is provided between the first electrode 30 and the second electrode 40.

A source interconnection 15 is provided on the source region 6. A drain interconnection 25 is provided on the drain region 7. The source interconnection 15 and the drain interconnection 25 extend on the isolation region 67 surrounding the device region 65. The source interconnection 15 and the drain interconnection 25 are connected to the drain region 7 and the source region 6 of the adjacent FET 60, respectively.

The gate electrodes 30 and 40 also extend on the isolation region 67 and are connected to gate interconnections 35 and 45. The gate interconnections 35 and 45 are connected to the gate terminal 70 through the gate resistors R_{G1} and R_{G2}, not shown, respectively (see FIG. 1).

On the other hand, the intermediate region 9 provided between the gate electrode 30 and the gate electrode 40 includes a portion extending from the device region 65 to the isolation region 67. The intermediate region 9 is connected to a control interconnection 55. The control interconnection 55 is electrically connected to the control terminal 50 through the control resistor R_{Ck}, not shown.

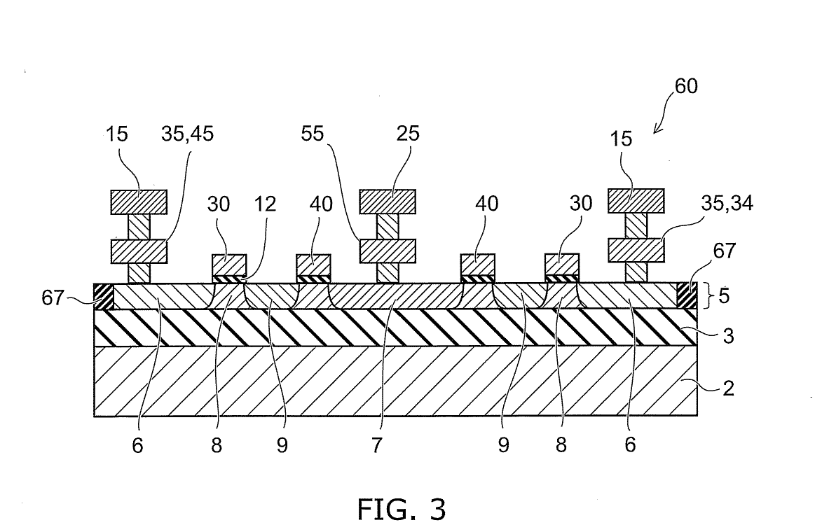

FIG. 3 schematically shows the A-A cross section of the FET 60. As shown in this figure, for instance, the FET 60 is provided in a semiconductor layer 5. The semiconductor layer 5 is an SOI film formed via an insulating layer 3 on a silicon substrate 2. For instance, the insulating layer 3 is a silicon dioxide (SiO₂) film, and the semiconductor layer 5 is a p-type silicon layer.

As shown in FIG. 3, the isolation region 67 is provided around the device region 65. For instance, the isolation region 67 is an SiO₂ film provided in the STI (shallow trench isolation) structure. In the device region 65, n⁺-silicon regions serving as the source region 6, the drain region 7, and the intermediate region 9 are selectively formed by e.g. ion implantation.

On the other hand, on the surface of the semiconductor layer 5, the gate electrodes 30 and 40 are provided via a gate insulating film 12. Then, for instance, by using the gate electrodes 30 and 40 as a mask, n-type impurity is ion implanted to form n⁺-silicon regions. Thus, a p-type body region 8 can be provided below the gate electrodes 30 and 40.

The FET 60 thus formed is e.g. an n-type MOSFET provided on the SOI structure, and is a dual gate FET including two gate electrodes. Instead of the SOI structure provided on the silicon substrate 2, it is also possible to use other structure in which the semiconductor layer 5 is provided on an insulative substrate such as a sapphire substrate.

Furthermore, the source interconnection 15 and the drain interconnection 25 are formed to be electrically connected to the source region 6 and the drain region 7. The source interconnection 15 and the drain interconnection 25 can be formed as multilayer interconnections. For instance, as shown in FIG. 3, the source interconnection 15 and the drain interconnection 25 can be provided as upper layer interconnections on the gate interconnections 35, 45 and the control interconnection 55.

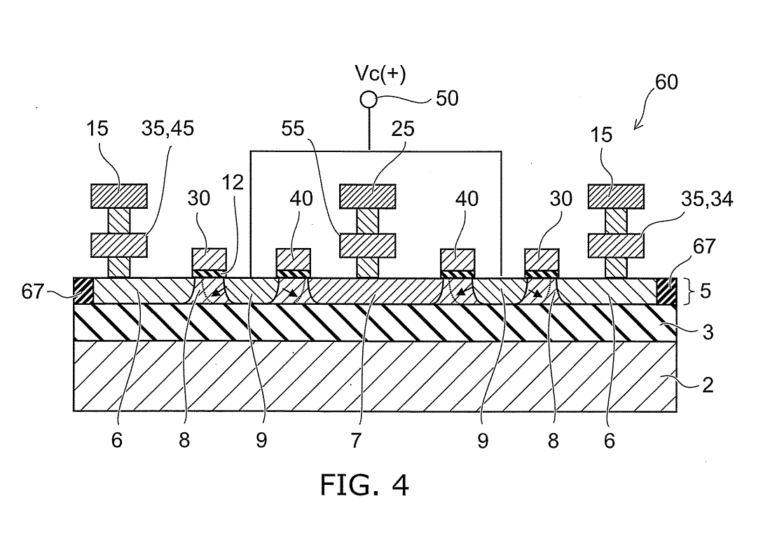

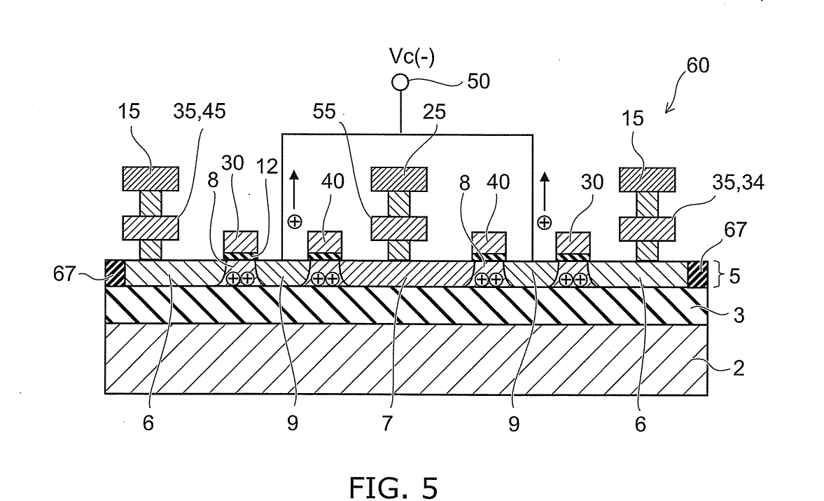

Next, the operation of the FET 60 is described with reference to FIGS. 4 and 5. FIG. 4 shows the FET 60 in the OFF state in which the control terminal 50 is supplied with a positive potential. FIG. 5 shows the state in which the control terminal 50 is supplied with a negative potential.

As shown in FIG. 4, with the FET 60 placed in the OFF state, the control terminal 50 is supplied with a positive potential. In this case, the pn junction between the intermediate region 9 and the p-type body region 8 below the gate electrodes 30 and 40 is reverse biased. Then, as indicated by arrows in this figure, inside the p-type body region 8, a depletion layer spreads from the gate edge portion. For instance, the p-type body region 8 may be entirely depleted. Thus, as compared with the case where the potential of the gate electrodes 30 and 40 is simply off-biased, the depletion layer width is widened. Hence, it becomes possible to improve the isolation characteristics and the source-drain breakdown voltage of the FET 60.

From a different viewpoint, the number of stages of the FETs 60 can be decreased corresponding to the improved amount of the source-drain breakdown voltage, since the breakdown voltage between the input terminal 10 and the output terminal 20 may be maintained under a positive potential supplied to the control terminal 50. That is, in addition to the reduction of the area of the source region 6 or the drain region 7 by dual gate configuration, area reduction can be achieved by decreasing the number of FET stages.

Furthermore, by decreasing the number of stages of the FETs 60, the on-resistance between the input terminal 10 and the output terminal 20 is also reduced. Accordingly, the gate width W_{g} (see FIG. 2) can also be narrowed without increasing the insertion loss of the switch circuit provided between the input terminal 10 and the output terminal 20.

Thus, the area of the FETs 60 can be significantly reduced by decreasing the number of FET stages and narrowing the gate width W_{g}. Hence, the area of the switch circuit including the FETs 60 can be reduced, and the semiconductor device equipped with the switch circuit can be downsized. Furthermore, downsizing the FETs 60 also decreases the charge amount for operation. This provides the additional advantage such as the downsizing of the power supply circuit or the enhancement of switching speed.

On the other hand, in the example shown in FIG. 5, when the FET 60 is in the OFF state, the control terminal 50 is supplied with a negative potential. In this case, the pn junction between the intermediate region 9 and the p-type body region 8 below the gate electrodes 30 and 40 is forward biased. Hence, the spread of the depletion layer in the p-type body region 8 is lost. However, as shown in this figure, holes accumulated in the p-type body region 8 can be extracted outside through the control terminal 50.

For instance, the p-type body region in the FET of the SOI structure is a box region surrounded with the insulating layer 3 and the n⁺-silicon regions (source region 6 and drain region 7). Thus, in the OFF state, the p-type body region is electrically isolated. Holes supplied to the p-type body region by the voltage amplitude of radio frequency signals, for instance, are not released outside, but accumulated inside the body region. This causes the decrease of the source-drain breakdown voltage and the variation of the source-drain capacitance during OFF time. This phenomenon modulates radio frequency signals and constitutes one of the factors causing harmonic distortion and intermodulation distortion.

In the viewpoint of suppressing distortion components attributed to FET, it is desirable to reduce the accumulation of holes in the body region. Therefore, in a semiconductor device using in the field requiring the linearity of radio frequency signals, the number of series connected FET stages is increased to decrease the voltage applied to each FET. Thereby, the holes supplied into the body region are reduced.

In contrast, in the FET 60 according to this embodiment, the holes accumulated in the p-type body region 8 below the gate electrodes 30 and 40 can be extracted by a negative potential applied to the control terminal 50. Thus, the distortion of radio frequency signals due to the accumulation of holes can be suppressed and it becomes possible to increase the voltage applied to the FET 60. Hence, the number of series connected stages of the FETs 60 can be decreased. As a result, the on-resistance between the input terminal 10 and the output terminal 20 can be reduced, and the insertion loss can be reduced.

Hence, as in the example shown in FIG. 4, decreasing the number of stages of the FETs 60 and narrowing the gate width W_{g} may reduce the area of the switch circuit. Thus, the semiconductor device equipped with the switch circuit can be downsized.

The operation control of the FET 60 shown in FIGS. 4 and 5 can be realized not only in a dual gate FET including two gate electrodes, but also in a multi-gate FET including two or more gate electrodes. Thus, it is possible to downsize the semiconductor device equipped with a switch circuit including multi-gate FETs.

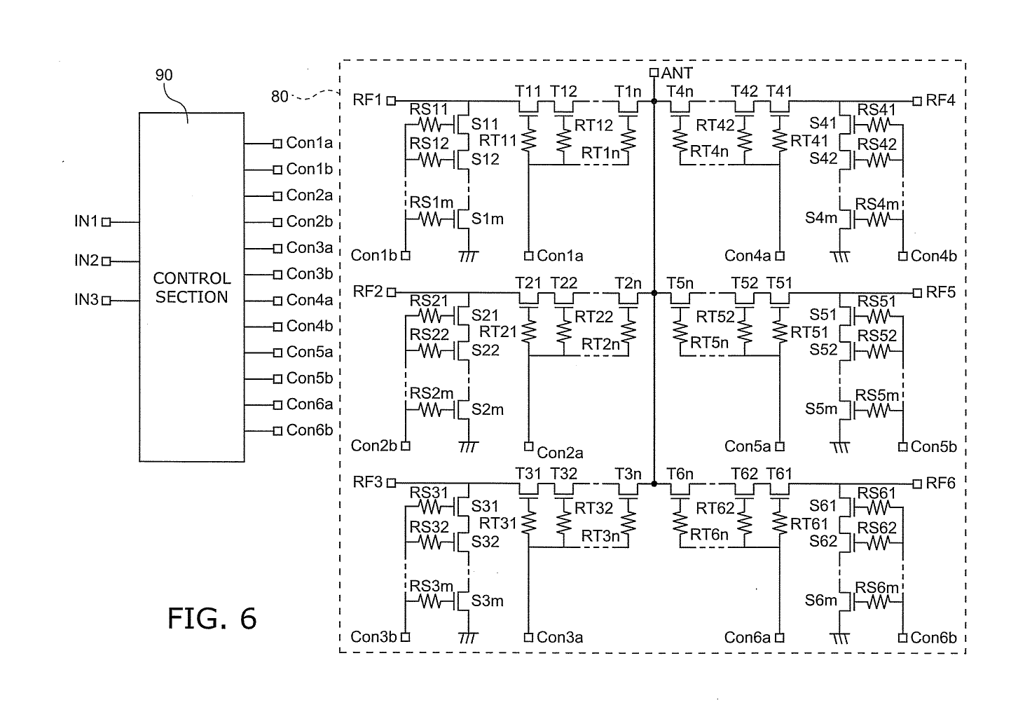

Next, a switch circuit of the semiconductor device is described with reference to FIG. 6. FIG. 6 illustrates the configuration of a semiconductor device including a switch circuit 80 and a control section 90. The switch circuit 80 enclosed with the dashed line in this figure is a so-called SP6T switch.

The switch circuit 80 switches the signal pathway between a common ANT terminal and radio frequency terminals RF1-RF6. For instance, series connected n-stage FETs (T11-T1n) are provided between the ANT terminal and RF1. Respective gates are connected to a common gate terminal Con1a through resistors RT11-RT1n.

A control signal is applied from the control section 90 to the gate terminal Con1a and turns on/off the FETs (T11-T1n). Thus, the signal pathway between the ANT terminal and the RF terminal is put in the ON state or the OFF state.

Furthermore, series connected m-stage FETs (S11-S1m) are provided also between RF1 and the ground terminal. The FETs (S11-S1m) are turned on/off by a control signal applied to the gate terminal Con1b. For instance, the FETs (S11-S1m) are controlled to be turned off when the FETs (T11-T1n) are in the ON state. The FETs (S11-S1m) are controlled to be turned on when the FETs (T11-T1n) are in the OFF state. Hence, when the FETs (T11-T1n) are turned off to block the signal pathway between the ANT terminal and RF1, RF1 is connected to the ground terminal. Thus, radio frequency signals leaking through the off-capacitance of the FETs (T11-T1n) can be prevented from being output to the circuit connected to RF1.

The signal pathways between the ANT terminal and other RF2-RF6 can be controlled likewise. The control section 90 decodes the control signal applied to the input terminals IN1-IN3 and outputs the result to the gate terminals Con1a-6b. Thus, the control section 90 controls the respective signal pathways between the ANT terminal and RF1-RF6.

For instance, every FET provided between the ANT terminal and RF1-6 can be replaced by the FET 60 according to the embodiment. Thus, the area of the switch circuit 80 can be significantly reduced. Hence, the semiconductor device equipped with the switch circuit 80 can be downsized. In this case, the control section 90 supplies a control voltage to the control terminal of the FET 60.

Here, in the switch circuit 80, in the case where a radio frequency signal is distributed from the ANT terminal to each of RF1-6, the ANT terminal serves as an input terminal, and each of RF1-6 serves as an output terminal. Conversely, in the case where a radio frequency signal is outputted from each RF terminal to the ANT terminal, each of RF1-6 serves as an input terminal, and the ANT terminal serves as an output terminal. It is understood that in the FET 60, the input from the source region 6 and the input from the drain region 7 are equivalent, which can simplify the configuration of the switch circuit 80.

In the case where the power of radio frequency signals input to the switch circuit is low, the FET 60 provided between the input terminal 10 and the output terminal 20 can be a single-stage FET. Then, for instance, by applying a negative potential to the control terminal 50, harmonic distortion and intermodulation distortion can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device including a switch circuit comprising:
a first gate electrode provided between a source region and a drain region of an FET;
a second gate electrode provided between the first gate electrode and the drain region; and
a control terminal electrically connected to an intermediate region between the first gate electrode and the second gate electrode, a ground potential being supplied to the control terminal corresponding to ON state of the FET, and a positive potential or a negative potential being supplied to the control terminal corresponding to OFF state of the FET.

2. The device according to claim 1, wherein the control terminal is connected to the intermediate region independently of the source region and the drain region.

3. The device according to claim 1, wherein a control resistor is provided between the control terminal and the intermediate region.

4. The device according to claim 1, further comprising:
a gate terminal electrically connected to the first gate electrode and the second gate electrode,
wherein a gate resistor is provided between the gate terminal and each of the first gate electrode and the second gate electrode.

5. The device according to claim 1, wherein a plurality of the FETs are connected in series between an input terminal and an output terminal of the switch circuit.

6. The device according to claim 5, wherein
the switch circuit includes a plurality of resistors connected in series between the input terminal and the output terminal, and
each of the resistors is connected in parallel with the FET, divides a voltage applied between the input terminal and the output terminal, and applies the divided voltage to the FET.

7. The device according to claim 6, wherein the voltage applied to each of the FETs is equal.

8. The device according to claim 1, wherein the FET turns on or off a signal pathway between the input terminal and the output terminal.

9. The device according to claim 1, wherein the switch circuit includes a control section configured to supply a control voltage to the control terminal.

10. The device according to claim 1, wherein
the switch circuit includes a plurality of the FETs, and
the FETs include the FET provided between the input terminal and the output terminal of the switch circuit, and the FET provided between the ground terminal and one of the input terminal and the output terminal.

11. The device according to claim 10, wherein
the switch circuit includes a control section configured to supply a control signal to the first gate electrode and the second gate electrode,
the control section turns off the FET provided between the ground terminal and one of the input terminal and the output terminal when the control section turns on the FET provided between the input terminal and the output terminal, and
the control section turns on the FET provided between the ground terminal and one of the input terminal and the output terminal when the control section turns off the FET provided between the input terminal and the output terminal.

12. The device according to claim 1, further comprising a semiconductor layer provided with the FET,
wherein the FET is provided in a device region surrounded with an isolation region in the semiconductor layer.

13. The device according to claim 12, wherein two of the source regions and two of the intermediate regions are arranged symmetrically in the surface of the semiconductor layer.

14. The device according to claim 12, wherein the FET has equivalent characteristics for input to the source region and input to the drain region.

15. The device according to claim 12, wherein the isolation region includes an SiO₂ film.

16. The device according to claim 1, further comprising a semiconductor layer provided with the FET,
wherein the source region, the drain region, and the intermediate region are n-type regions, and
each of the semiconductor layer below the first gate electrode and the semiconductor layer below the second gate electrode includes a p-type region.

17. The device according to claim 16, wherein the p-type region is depleted when the positive potential is supplies to the control terminal.

18. The device according to claim 16, wherein holes are released from the p-type region through the control terminal when the negative potential is supplied to the control terminal.

19. The device according to claim 1, further comprising a semiconductor layer provided with the FET,
wherein the semiconductor layer is an SOI (silicon on insulator) layer provided on a silicon substrate.

20. The device according to claim 1, further comprising a semiconductor layer provided with the FET,
wherein the semiconductor layer is provided on an insulating substrate.
